(19) United States
(12) Patent Application Publication
(10) Pub. No.: US 2002/0014196 A1
(43) Pub. Date: Feb. 7, 2002

(54) Piezoelectric ceramic material

(76) Inventors: Masanori Takase, Inazawa-shi (JP); Kazushige Ohbayashi, Nagoya-shi (JP)

Correspondence Address: LARSON & TAYLOR, PLC, 1199 NORTH FAIRFAX STREET, SUITE 900, ALEXANDRIA, VA, 22314, US

(21) Appl. No.: 09/779,446

(22) Filed: Feb. 9, 2001

(30) Foreign Application Priority Data
Aug. 10, 1999 (JP) 11-226581

(51) Int. Cl. C30B 33/06

(52) U.S. Cl. 117/1

(57) ABSTRACT

A lead-free piezoelectric ceramic material is provided having a large piezoelectric strain constant which exhibits low temperature dependence. The piezoelectric ceramic material includes Ba, Bi, Na, Ti, and O, in the molar ratio of: 0.997≦Bi/Na≦1.003, and Ba/Bi=2x/(a-x) wherein 0.99≦a≦1.01, 0<x<a. The piezoelectric ceramic material may be employed for producing piezoelectric devices such as oscillators, actuators, sensors and filters.

### BACKGROUND OF THE INVENTION

1. Field of the Invention

The present invention relates to a piezoelectric ceramic material and, more particularly, to a lead-free piezoelectric ceramic material which has a large piezoelectric strain constant and whose piezoelectric strain constant exhibits low dependence on temperature.

2. Background of the Invention

The majority of conventionally mass-produced piezoelectric ceramic materials are piezoelectric ceramic materials containing lead and/or lead oxide, such as PT (lead titanate) and PZT (lead titanate zirconate). However, firing of such lead-containing piezoelectric ceramic materials necessarily involves evaporation of lead oxide and similar related substances and this obviously has adverse environmental effects. The treatment of lead or a lead compound without producing adverse effects on the environment can be carried out but at high cost, among other disadvantages. Therefore, there has been keen demand for a lead-free piezoelectric ceramic material.

Recently, (Bi_{0.5}Na_{0.5})TiO₃ (hereinafter “BNT”) and bismuth-lamellar compounds have become of interest as lead-free piezoelectric ceramic materials. However, as compared with a lead-containing piezoelectric ceramic material, such a lead-free material has a small piezoelectric strain constant, the strain of the material is small with respect to a voltage applied thereto, and the voltage generated from the material is small with respect to a stress applied thereto. Therefore, employment of such a lead-free piezoelectric ceramic material is of limited value in the production of an active element such as an oscillator.

Japanese Patent Publication (kokoku) No. 4-60073 B discloses a piezoelectric ceramic material containing BNT as a component. This publication discloses a new composition of lead-free piezoelectric ceramic material. However, the piezoelectric strain constant of the material disclosed in the publication is at most 99×10⁻¹² C/N. Although the publication is silent about temperature dependence of the piezoelectric strain constant, the temperature coefficient of the piezoelectric strain constant of the piezoelectric ceramic material must be nearly equal to zero, in order for the material to exhibit consistent performance over a wide temperature range.

### BRIEF SUMMARY OF THE INVENTION

The present invention relates to a lead-free piezoelectric ceramic material having a large piezoelectric strain constant. The piezoelectric ceramic material of the present invention may be employed for producing piezoelectric devices such as oscillators, actuators, sensors, and filters. In an optimal embodiment, the lead-free piezoelectric ceramic material has a large piezoelectric strain constant which exhibits low temperature dependence.

According to one aspect of the invention, there is provided a piezoelectric ceramic material containing Ba, Bi, Na, Ti, and O, having molar relationships of 0.990<Bi/Na≦1.01, and Ba/Bi=2x/(a-x) wherein 0.99≦a≦1.01, and 0<x<a.

Further features and advantages of the present invention will be set forth in, or apparent from, the detailed description of preferred embodiments thereof which follows.

### DETAILED DESCRIPTION OF THE INVENTION

As indicated above, according to one aspect of the invention, the piezoelectric ceramic material contains Ba, Bi, Na, Ti and O having the molar ratio of 0.990<Bi/Na≦1.01 Ba/Bi=2x/(a-x) wherein 0.99≦a≦1.01 and 0<x<a. When the aforementioned Bi/Na and Ba/Bi ratios fall outside the above respective ranges, the piezoelectric strain constant of the material tends to be small.

In accordance with a second aspect of the invention, the piezoelectric ceramic material is preferably represented by the following chemical formula: xBaTiO₃-(a-x)(Bi_{b}Na_{c})TiO₃. Optimally, the piezoelectric ceramic material is a solid material and has a perovskite-type structure. However, the ceramic material may have a structure including a perovskite phase as a primary crystalline phase. The ceramic material may also have a structure including other crystalline phases, so long as the phases do not impair the piezoelectric characteristics of the material. In the above chemical formula, b and c satisfy the relation 0.990<b/c<1.01.

In accordance with a third aspect of the invention, the quantity x in the above chemical formula is preferably within the range of 0.05 and 0.5. When x is less than 0.05 or in excess of 0.5, the piezoelectric strain constant of the piezoelectric ceramic material tends to be lowered. The lower limit of x is determined to be 0.05, since the morphotropic phase boundary may exist in the vicinity of the composition in which x=0.05 to 0.06. Therefore, when x is less than 0.05, the piezoelectric strain constant of the piezoelectric ceramic material decreases drastically, and thus obtaining a large piezoelectric strain constant (e.g., 170×10⁻¹² C/N or more) may be difficult.

More preferably, x is between 0.1 and 0.5 inclusive, much more preferably, between 0.2 and 0.5 inclusive. When x falls within the above range, a notably large piezoelectric strain constant can be obtained. In addition, temperature dependence of the piezoelectric strain constant is reduced. When x falls within the above range, the resultant composition contains a large amount of barium titanate as a solid solution, as compared with the composition in which the morphotropic phase boundary exists.

In accordance with a fourth aspect of the invention, when x falls within the preferable range of the third aspect, the piezoelectric ceramic material has a piezoelectric strain constant at 20° C. (d₃₃^{20° C.}) as measured according to EMAS-6100 (standards by Denshi Zairyo Kogyokai) of 100×10⁻¹² C/N or more (usually 170×10⁻¹² C/N or less, preferably 100×10⁻¹² to 160×10⁻¹² C/N, more preferably 110×10⁻¹² to 160×10⁻¹² C/N).

A temperature coefficient of the piezoelectric strain constant d₃₃t is calculated on the basis of formula d₃₃t (%/° C.)=(d₃₃^{80° C.-d}₃₃^{20° C.})/((80° C.−20° C.)×d₃₃^{20° C.})×100. The temperature coefficient d₃₃t is 0.15%/° C. or less (usually 0.05%/° C. or more, preferably 0.08 to 0.12%/° C., more preferably 0.08 to 0.11%/° C.).

The values d₃₃^{20° C. and d}₃₃t can be attained simultaneously. Briefly, when d₃₃^{20° C.} is 100×10⁻¹² C/N or more (usually 170×10⁻¹² C/N or less), d₃₃t is 0.15%/° C. or less (usually 0.05%/° C. or more).

In accordance with a fifth aspect of the invention, the piezoelectric ceramic material more preferably has d₃₃^{20° C.} of 105×10⁻¹² to 150×10⁻¹² C/N and d₃₃t of 0.05 to 0.14%/° C., much more preferably d₃₃^{20° C.} of 110×10⁻¹² to 135×10⁻¹² C/N and d₃₃t of 0.08 to 0.12%/° C.

Referring generally to all aspects of the invention described above, the piezoelectric ceramic material preferably has a large piezoelectric output constant (g₃₃), as well as a large piezoelectric strain constant. Accordingly, a piezoelectric ceramic material having g₃₃ of 18×10⁻³ to 21×10⁻³ V·m/N can be produced. Such a piezoelectric ceramic material is applicable to production of an active element or a passive element.

It will be understood that the piezoelectric characteristics of a piezoelectric ceramic material can vary greatly with slight changes in the amount of a particular component contained in the material. In other words, even when a number of piezoelectric ceramic materials contain the same elements, the piezoelectric characteristics of the materials can differ greatly from one another based on the different amounts of the elements contained thereof and the different proportions of the elements.

The piezoelectric ceramic material of the present invention contains constituents in proportions which are materially different than those in previously available piezoelectric ceramic material. Although the piezoelectric ceramic material disclosed in Japanese Patent Publication No. 4-60073 contains the same elements as those contained in the piezoelectric ceramic material of the present invention, the proportions of the elements contained in the former material differ from those of the elements contained in the latter material. In particular, the amount of Ba contained in the material of the present invention is greater than that of Ba contained in the material disclosed in the publication. More specifically, the amount of barium titanate contained in the material of the present invention is greater than that of barium titanate contained in the material disclosed in the publication. In addition, the material of the present invention differs from the material disclosed in the publication in that the material of the present invention contains Na and Bi in substantially the same amounts.

In accordance with the first aspect of the invention discussed above, there can be produced a piezoelectric ceramic material which has a piezoelectric strain constant larger than that of a conventional BNT piezoelectric ceramic material. In accordance with the second through fifth aspects, there can be produced a piezoelectric ceramic material which has a large piezoelectric strain constant that exhibits low temperature dependence.

### EXAMPLE

The present invention will next be described in detail by way of examples. It will be understood that these examples are presented not to limit the scope of the present invention but rather to provide enhanced understanding of the present invention.

(1) Production of Piezoelectric Ceramic Material and Piezoelectric Element

Commercially available BaCO₃ powder, Bi₂O₃ powder, Na₂CO₃ powder, and TiO₂ powder were weighed so as to attain the compositional proportions shown in Table 1. These powders and ethanol were placed in a ball mill, and then wet-mixed for 15 hours. The resultant slurry was dried in a hot-water bath, and then calcined in air at 800° C. for two hours. Subsequently, the calcined product, an organic binder, a dispersant, and ethanol were placed in a ball mill, and then wet-mixed for 15 hours. Subsequently, the resultant slurry was dried in a hot-water bath for granulation, and the granules were formed into a column-shaped product having a diameter of 5 mm and a thickness of 15 mm, through uniaxial pressing at 1 GPa. Thereafter, the product was subjected to cold isostatic pressing (CIP) at 15 Gpa, and the resultant product was fired in air at 1,050-1,250° C. for two hours, to thereby produce a piezoelectric ceramic material. In Table 1, the samples marked with an asterisk (*) fall outside the scope of the present invention.

TABLE 1

| | | Composition | x | a | Bi/Na |
|---|---|---|---|---|---|
| Test Example | *1 | Bi_{0.500}Na_{0.500}TiO₃ | 0.000 | 1.00 | 1.000 |
| | 2 | Ba_{0.090}Bi_{0.455}Na_{0.455}TiO₃ | 0.090 | 1.00 | 1.000 |
| | 3 | Ba_{0.210}Bi_{0.395}Na_{0.395}TiO₃ | 0.210 | 1.00 | 1.000 |
| | 4 | Ba_{0.240}Bi_{0.380}Na_{0.380}TiO₃ | 0.240 | 1.00 | 1.000 |
| | 5 | Ba_{0.300}Bi_{0.350}Na_{0.350}TiO₃ | 0.300 | 1.00 | 1.000 |
| | 6 | Ba_{0.420}Bi_{0.290}Na_{0.290}TiO₃ | 0.420 | 1.00 | 1.000 |
| | 7 | Ba_{0.480}Bi_{0.260}Na_{0.260}TiO₃ | 0.480 | 1.00 | 1.000 |
| | 8 | Ba_{0.510}Bi_{0.245}Na_{0.245}TiO₃ | 0.510 | 1.00 | 1.000 |
| | *9 | Ba_{0.005}Bi_{0.495}Na_{0.500}TiO₃ | 0.005 | — | 0.990 |

Subsequently, the upper and lower surfaces of the produced piezoelectric ceramic material were subjected to polishing. Then, a silver paste was applied to both surfaces through screen printing, and baking was carried out, to thereby form an electrode. Thereafter, the electrode was subjected to polarization treatment in insulating oil (silicone oil) maintained at 10-200° C., through application of a direct current of 3-7 kV/mm for 30 minutes, to thereby produce a piezoelectric element.

(2) Measurement of Piezoelectric Characteristics

According to EMAS-6100, the piezoelectric strain constant (d₃₃^{20° C.) and the piezoelectric output constant (g}₃₃) of each of the piezoelectric elements produced in (1) were measured in a thermostatic chamber maintained at 20° C., by use of an impedance analyzer (model: 4149A, product of Hewleft Packard). The results are shown in Table 2.

Similarly, the piezoelectric strain constant (d₃₃^{80° C.) of the piezoelectric element was measured in a thermostatic chamber maintained at} 80° C. The thus-measured d₃₃^{80° C.} and the above-measured d₃₃^{20° C. were substituted into formula (}1), to thereby calculate d₃₃t. The results are also shown in Table 2. In Table 2, the samples marked with an asterisk (*) fall outside the scope of the present invention.

TABLE 2

| | | d₃₃^{20° C.} | d₃₃t | g₃₃ |
|---|---|---|---|---|
| | | (×10⁻¹² C/N) | (%/° C.) | (×10⁻³ V · m/N) |
| Test Example | *1 | 73 | 0.31 | 17 |
| | 2 | 159 | 0.33 | 18 |
| | 3 | 131 | 0.12 | 21 |
| | 4 | 118 | 0.08 | 21 |
| | 5 | 111 | 0.09 | 20 |
| | 6 | 103 | 0.09 | 21 |
| | 7 | 92 | 0.11 | 20 |
| | 8 | 76 | 0.33 | 17 |
| | *9 | 64 | 0.30 | 15 |

As is apparent from Table 2, the piezoelectric elements of Test Example 2 through 8 (i.e., the element of the present invention), in which x falls within a range of 0.05 to 0.5, have large piezoelectric strain constants (76×10⁻¹² to 159×10⁻¹² C/N). More particularly, in the piezoelectric elements of Test Examples 3 through 7, wherein x falls within range of 0.2 to 0.5, the temperature coefficient is as small as 0.08 to 0.12%/° C. (i.e., the temperature dependence is low), and the piezoelectric strain constant is as large as 92×10⁻¹² to 131×10⁻¹² C/N. In contrast, in the element of Test Example 9 wherein the ratio by mol of Bi/Na is 0.990, the piezoelectric strain constant is small.

Again, the present invention is not limited to the specific examples set forth above, and in accordance with purpose and use, various modifications may be made within the scope of the invention. For example, the piezoelectric ceramic material of the present invention may contain Li and K as components. Li or K may assume any form in the ceramic material, but these elements are preferably substituted for some Na atoms contained in BNT. The piezoelectric ceramic material of the present invention may contain, in addition to the above components, other components or unavoidable impurities, so long as they do not substantially affect piezoelectric characteristics of the ceramic material.

Although the invention has been described above in relation to preferred embodiments thereof, it will be understood by those skilled in the art that variations and modifications can be effected in these preferred embodiments without departing from the scope and spirit of the invention.

What is claimed is:

1. A composition comprising:
a piezoelectric ceramic material comprising Ba, Bi, Na, Ti, and O and having molar relationships of
0.990<Bi/Na≦1.01; and
Ba/Bi=2x/(a-x) wherein 0.99≦a≦1.01, 0<x<a.

2. The composition according to claim 1, wherein said piezoelectric ceramic material is represented by the chemical formula:
xBaTiO₃−(a-x)(Bi_{b}Na_{c})TiO₃,
wherein b and c satisfy the relation 0.990<b/c≦1.01.

3. The composition according to claim 2, wherein x is between 0.05 and 0.5.

4. The composition according to claim 1, wherein said piezoelectric ceramic material has:
a piezoelectric strain constant, d₃₃^{20° C.}, of at least 100×10⁻¹² C/N at 20° C.; and
a temperature coefficient, d₃₃t, of no greater than 0.15%/° C.

5. The composition according to claim 2, wherein said piezoelectric ceramic material has:
a piezoelectric strain constant, d₃₃^{20° C.}, of at least 100×10⁻¹² C/N at 20° C.; and
a temperature coefficient, d₃₃t, of no greater than 0.15%/° C.

6. The composition according to claim 3, wherein said piezoelectric ceramic material has:
a piezoelectric strain constant, d₃₃^{20° C.}, of at least 100×10⁻¹² C/N at 20° C.; and
a temperature coefficient, d₃₃t, of no greater than 0.15%/° C.

7. The composition according to claim 4, wherein
105×10⁻¹²<d₃₃^{20° C.} C/N<150×10⁻¹², and 0.05<d₃₃t %/° C.<0.14.

8. The composition according to claim 5, wherein
105×10⁻¹²<d₃₃^{20° C.} C/N<150×10⁻¹², and 0.05<d₃₃t %/° C.<0.14.

9. The composition according to claim 6, wherein
105×10⁻¹²<d₃₃^{20° C.} C/N<150×10⁻¹², and 0.05<d₃₃t %/° C.<0.14.

10. The composition according to claim 4, wherein said temperature coefficient, d₃₃t, is derived from the formula:
d₃₃t(%/° C.)=(d₃₃^{80° C.}−d₃₃^{20° C.})/((80° C.−20° C.)×d₃₃^{20° C.})×100,
wherein d₃₃^{80° C.} is a piezoelectric strain constant at 80° C.

11. The composition according to claim 5, wherein said temperature coefficient, d₃₃t, is derived from the formula:
d₃₃t(%/° C.)=(d₃₃^{80° C.}−d₃₃^{20° C.})/((80° C.−20° )×d₃₃^{20° C.})×100,
wherein d₃₃^{80° C.} is a piezoelectric strain constant at 80° C.

12. The composition according to claim 6, wherein said temperature coefficient, d₃₃t, is derived from the formula:
d₃₃t(%/° C.)=(d₃₃^{80° C.}−d₃₃^{20° C.})/((80° C.−20° C.)×d₃₃^{20° C.})×100,
wherein d₃₃^{80° C.} is a piezoelectric strain constant at 80° C.
